(19) United States
(12) Patent Application Publication
(10) Pub. No.: US 2026/0028975 A1
(43) Pub. Date: Jan. 29, 2026

(54) PROTECTIVE COATINGS FOR CRYOGENIC PUMP COMPONENTS IN PROCESS CHAMBERS

(71) Applicant: APPLIED MATERIALS, INC., Santa Clara, CA (US)

(72) Inventors: Justin Chiang Gau, Sunnyvale, CA (US); Dmitry Lubomirsky, Cupertino, CA (US); Rahul Kozhikkalkandi, Santa Clara, CA (US); Arun Chakravarthy Chakravarthy, Cupertino, CA (US)

(21) Appl. No.: 18/787,431

(22) Filed: Jul. 29, 2024

(51) Int. Cl. F04B 37/08; C23C 16/40; F04B 37/14; F25B 9/00

(52) U.S. Cl. CPC F04B 37/085; C23C 16/405; F04B 37/14; F25B 9/002

(57) ABSTRACT

A cryogenic pump includes a refrigeration unit and a cryogenic plate coupled with the refrigeration unit. The cryogenic plate includes a plate body and a protective coating on at least one surface of the plate body. The protective coating includes at least one of a rare earth oxide or SiO₂.

### TECHNICAL FIELD

Embodiments disclosed herein relate, in general, to protective coatings for cryogenic pump components in process chambers, and in particular to corrosion and/or erosion resistant ceramic material coatings for cryogenic pump components.

### BACKGROUND

In the semiconductor industry, devices are fabricated by a number of manufacturing processes producing structures of an ever-decreasing size. As device geometries shrink, susceptibility to defects and particle contamination increases, and particle contaminant specifications become more stringent. To minimize defects and contamination introduced during chamber processing, such as contamination due to H₂O (i.e., moisture or water contamination, etc.), cryogenic pumps are used to reduce the partial pressure of H₂O (e.g., water) within the processing chamber. The components of a cryogenic pump can also be exposed to etchants in the processing chamber, such as chlorine. Exposure to both H₂O and chlorine can form liquid HCL on the cryogenic pump, causing erosion or other degradation to the cryogenic pump.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular embodiments of the disclosure or any scope of the claims. Its sole purpose is to present some concepts of the disclosure in a simplified form as a prelude to the more detailed description that is presented later.

In one aspect of the present disclosure, a cryogenic pump includes a refrigeration unit and a cryogenic plate coupled with the refrigeration unit. The cryogenic plate includes a plate body and a protective coating on at least one surface of the plate body. The protective coating includes at least one of a rare earth oxide or SiO₂.

In another aspect of the present disclosure, a method includes forming a protective coating on at least one surface of a cryogenic plate body. The protective coating includes at least one of a rare earth oxide or SiO₂.

In a further aspect of the present disclosure, a process chamber includes a chamber body and a cryogenic plate disposed within the chamber body. The cryogenic plate includes a plate body and a protective coating on at least one surface of the plate body. The protective coating includes at least one of a rare earth oxide or SiO₂.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1A is a sectional view of a processing chamber having a cryogenic pump that is at least partially coated with a protective coating material, according to some embodiments.

FIG. 1B is a simplified schematic diagram of a substrate processing system that includes a cryogenic pump, according to some embodiments.

FIG. 1C is a simplified schematic diagram of a cryogenic pump, according to some embodiments.

FIG. 2 is a sectional view of a coated article, according to some embodiments.

FIG. 3 discloses a method for coating an article, according to some embodiments.

FIG. 4A depicts a deposition mechanism applicable to a variety of deposition techniques utilizing energetic particles such as ion assisted deposition (IAD), according to some embodiments.

FIG. 4B depicts a schematic of an IAD deposition apparatus that may be utilized for coating an article, according to some embodiments.

FIG. 5 depicts an exemplary CVD system that may be utilized for coating an article, according to some embodiments.

FIG. 6 depicts an exemplary PVD system that may be utilized for coating an article, according to some embodiments.

FIG. 7 illustrates a cross-sectional view of a system for plasma spraying a protective coating on an article, in accordance with an embodiment.

FIG. 8 depicts a mechanism applicable to a variety of ALD techniques that may be utilized for coating an article, according to some embodiments.

### DETAILED DESCRIPTION OF EMBODIMENTS

Embodiments of the present disclosure provide a cryogenic pump (e.g., a cryogenic pump for use in a substrate processing chamber) having a protective coating.

Substrate processes may be sensitive to contaminants. One such contaminant is oxygen and another such contaminant is hydrogen. The presence of water (i.e., H₂O) can adversely affect a substrate process. Therefore, in some embodiments, it may be advantageous to reduce H₂O partial pressure within substrate processing chambers. To effectively reduce H₂O partial pressure, a cryogenic water pump can be used.

In some embodiments, a cryogenic pump (e.g., a cryogenic water pump) includes a plate (e.g., a cryogenic plate, etc.) that is cooled to a cryogenic temperature. For example, and in some embodiments, the plate may be cooled to a temperature less than approximately 200 Kelvin. In some embodiments, the plate may be cooled to a temperature of approximately 150 Kelvin. A refrigeration unit coupled with the plate may cool a refrigerant that is circulated through interior passages to cool the plate to a cryogenic temperature. In some embodiments, the refrigerant is a gas such as helium. The cryogenic plate material may be chosen for its high thermal conductivity. For example, and in some embodiments, the plate may be formed from a material such as copper and/or aluminum.

When water vapor in the environment within the processing chamber contacts the cooled cryogenic plate, the water vapor may quickly condense and then freeze on the surface of the plate. When the water vapor condenses and freezes, the water is removed from the environment in the processing chamber, reducing the partial pressure of H₂O in the chamber environment. Reduction of the partial pressure of H₂O in the chamber environment may reduce the contaminants (e.g., due to the presence of H₂O) in the processing chamber environment. Additional contaminants can include copper, aluminum, iron, and/or other metals, etc. which can affect the electrical properties of a film grown on a substrate.

Because the cryogenic plate is exposed to the environment within the processing chamber, the plate may be exposed to corrosive etchants, such as chlorine or other etchant gases, etc. In some embodiments, the etchant combines with condensed and/or frozen water on the cryogenic plate to form corrosive substances. For example, a chlorine gas etchant may react with water on the cryogenic plate to form liquid hydrogen chloride (HCL) which may corrode or otherwise degrade the cryogenic plate. Some conventional cryogenic plates have a nickel plating. However, a nickel plating is not sufficiently durable for extended use without being negatively affected by process chemistries (e.g., corrosive etchants, etc.) within the processing chamber.

Embodiments described herein provide a cryogenic pump having a cryogenic plate covered with a protective coating. In some embodiments, the cryogenic pump includes a refrigeration unit to cool a refrigerant. The cryogenic pump includes a cryogenic plate coupled with the refrigeration unit. The cryogenic plate may be cooled to a cryogenic temperature by the refrigerant. For example, and in some embodiments, the cryogenic plate is cooled by the refrigerant to a temperature less than approximately 200K, such as approximately 150 Kelvin, so that water vapor exposed to the cryogenic plate may condense and then freeze on the cryogenic plate.

In some embodiments, the cryogenic plate includes a plate body. The plate body may be made of a thermally conductive material. For example, and in some embodiments, the plate body is made up of copper, aluminum, or another suitable thermally conductive material. The plate body may form the interior passages through which cooled refrigerant can be circulated to cool the plate. In some embodiments, a protective coating is disposed on at least one surface of the plate body. For example, the protective coating may cover a top surface and/or a bottom surface of the plate body. In some embodiments, the protective coating is disposed on every surface of the cryogenic pump that is exposed to the environment within the processing chamber. For example, the cryogenic plate, any associated refrigeration tubing, fittings, and/or fixtures, etc. of the cryogenic pump which are disposed within the processing chamber may be coated with the protective coating.

In some embodiments, the protective coating includes one of a rare earth oxide or SiO₂. The rare earth oxide may include a rare earth metal such as yttrium. In some embodiments, the protective coating includes Y₃AL₅O₁₂ (YAG) or a solid solution of Y₂O₃ and ZrO₂. In some embodiments, the protective coating includes Y₂O₃. The protective coating may be resistant to corrosion, such as corrosion caused by etchants used in substrate processing. For example, the protective coating may be resistant to HCL corrosion.

The protective coating may be a dense thin film coating. For example, and in some embodiments, the protective coating may substantially lack porosity, contributing to substantial uniformity of the protective coating. In some embodiments, the protective coating is made up of a thin layer of material, such as having a thickness between a few nanometers to several micrometers. In some embodiments, the protective coating does not materially alter the thermal conductance of the plate body. Therefore, the protective coating may not degrade the plate body's ability to freeze and trap moisture, etc. For example, the protective coating does not act as a thermal insulator between the plate body and the environment within the processing chamber. Heat may be absorbed from the moisture in the environment and the moisture may condense and freeze on the plate body uninhibited by the protective coating.

Embodiments of the present disclosure provide advantages over conventional solutions. For example, some embodiments described herein provide a cryogenic pump that can effectively reduce partial pressure of H₂O within a processing chamber environment while also being resistant to corrosion. The cryogenic pump described herein can reduce contaminants in substrate processing chambers, such as reduction of H₂O, copper, aluminum, iron, and/or other metals. The cryogenic pump may reduce the amount of H₂O in the processing chamber, while the protective coating on the cryogenic pump may decrease the amount of metal particles introduced into the chamber. Additionally, the cryogenic pump described herein may have a longer service life when compared to conventional cryogenic pumps, such as those with nickel-plated coatings on the cryogenic plate. A processing chamber utilizing a cryogenic pump described herein may therefore have a longer time between maintenance, resulting in less down time and higher overall system throughput.

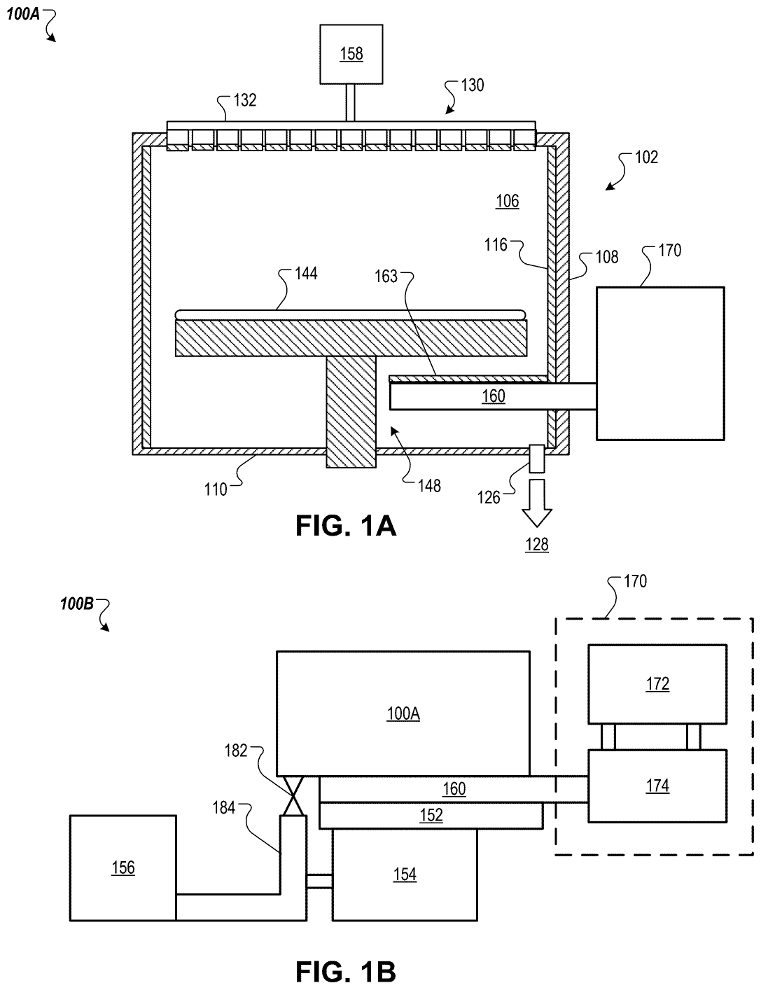

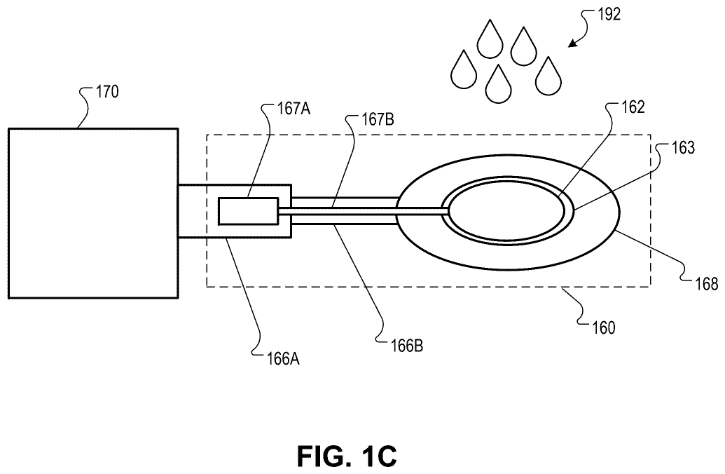

FIG. 1A is a sectional view of a processing chamber 100A (e.g., a substrate process chamber) having a cryogenic pump that includes a protective coating in accordance with embodiments described herein. The processing chamber 100A may be used for processes in which a corrosive plasma environment is provided. For example, the processing chamber 100A may be a chamber for a plasma etch reactor (also known as a plasma etcher), a plasma cleaner, a plasma-enhanced deposition chamber (e.g., for chemical vapor deposition, physical vapor deposition, atomic layer deposition, etc.), and so forth. In some embodiments, processing chamber 100A is an epitaxial reactor for performing epitaxy operations.

In one embodiment, the processing chamber 100A includes a chamber body 102 and a showerhead 130 that enclose an interior volume 106. The showerhead 130 may or may not include a gas distribution plate. For example, the showerhead may be a multi-piece showerhead that includes a showerhead base and a showerhead gas distribution plate bonded to the showerhead base. Alternatively, the showerhead 130 may be replaced by a lid and a nozzle in some embodiments, or by multiple pie shaped showerhead compartments and plasma generation units in other embodiments. The chamber body 102 may be fabricated from aluminum, stainless steel or other suitable material. The chamber body 102 generally includes sidewalls 108 and a bottom 110.

An outer liner 116 may be disposed adjacent the sidewalls 108 to protect the chamber body 102. The outer liner 116 may be a halogen-containing gas resistant material such as Al₂O₃ or Y₂O₃.

An exhaust port 126 may be defined in the chamber body 102 and may couple the interior volume 106 to a pump system 128. The pump system 128 may include one or more pumps and throttle valves utilized to evacuate and regulate the pressure of the interior volume 106 of the processing chamber 100A. More details regarding the one or more pumps and throttle valves may be described herein below with respect to FIG. 1B.

The showerhead 130 may be supported on the sidewalls 108 of the chamber body 102 and/or on a top portion of the chamber body. The showerhead 130 (or lid) may be opened to allow access to the interior volume 106 of the processing chamber 100A and may provide a seal for the processing chamber 100A while closed. A gas panel 158 may be coupled to the processing chamber 100A to provide process and/or cleaning gases to the interior volume 106 through the showerhead 130 or lid and nozzle. Showerhead 130 may be used for processing chambers used for dielectric etch (etching of dielectric materials). The showerhead 130 includes multiple gas delivery holes 132 throughout the showerhead 130. The showerhead 130 may be aluminum, anodized aluminum, an aluminum alloy (e.g., Al 6061), or an anodized aluminum alloy. In some embodiments, the showerhead includes a gas distribution plate (GDP) bonded to the showerhead. The GDP may be, for example, Si or SiC. The GDP may additionally include multiple holes that line up with the holes in the showerhead.

Examples of processing gases that may be used to process substrates in the processing chamber 100A include halogen-containing gases, such as C₂F₆, SF₆, SiCl₄, HBr, NF₃, CF₄, CHF₃, CH₂F₃, F, Cl₂, CCl₄, BCl₃ and SiF₄, among others, and other gases such as O₂, or N₂O. Examples of carrier gases include N₂, He, Ar, and other gases inert to process gases (e.g., non-reactive gases).

A substrate support assembly 148 is disposed in the interior volume 106 of the processing chamber 100A below the showerhead 130. The substrate support assembly 148 holds a substrate 144 (e.g., a wafer) during processing. The substrate support assembly 148 may include an electrostatic chuck that secures the substrate 144 during processing, a metal cooling plate bonded to the electrostatic chuck, and/or one or more additional components. An inner liner (not shown) may cover a periphery of the substrate support assembly 148. The inner liner may be a halogen-containing gas resistant material such as Al₂O₃ or Y₂O₃. The inner liner may also be coated with a protective ceramic material coating, in accordance with an embodiment.

A cryogenic pump 160 may is disposed at least partially within the interior volume 106 of the processing chamber 100A. The cryogenic pump 160 may be coupled with a refrigeration unit 170 that provides cooled refrigerant to the cryogenic pump 160. A plate of the cryogenic pump 160 may be cooled to a cryogenic temperature by the refrigerant so that water vapor within the interior volume 106 condenses and/or freezes on the plate. Condensing and/or freezing of water on the plate may reduce the partial pressure of H₂O within the interior volume 106. In some embodiments, the refrigeration unit 170 is configured to cool the plate of the cryogenic pump 160 to an operating temperature. The operating temperature may be less than approximately 200 Kelvin, such as approximately 150 Kelvin.

In some embodiments, the cryogenic pump 160 includes a protective coating 163 on at least one surface. In some embodiments, the protective coating 163 may be a protective ceramic material coating. In some embodiments, the protective coating 163 may include a rare earth oxide or SiO₂. In some embodiments, the protective coating 163 includes at least one of Y₃Al₅O₁₂ (YAG), a solid solution of Y₂O₃ and ZrO₂, or a compound comprising Y₄Al₂O₉ and a solid-solution of Y₂O₃—ZrO₂. With reference to the solid-solution of Y₂O₃—ZrO₂, the material may include Y₂O₃ at a concentration of 10-90 molar ratio (mol %) and ZrO₂ at a concentration of 10-90 mol %. In some examples, the solid-solution of Y₂O₃—ZrO₂ may include 10-20 mol % Y₂O₃ and 80-90 mol % ZrO₂, may include 20-30 mol % Y₂O₃ and 70-80 mol % ZrO₂, may include 30-40 mol % Y₂O₃ and 60-70 mol % ZrO₂, may include 40-50 mol % Y₂O₃ and 50-60 mol % ZrO₂, may include 60-70 mol % Y₂O₃ and 30-40 mol % ZrO₂, may include 70-80 mol % Y₂O₃ and 20-30 mol % ZrO₂, may include 80-90 mol % Y₂O₃ and 10-20 mol % ZrO₂, and so on. With reference to the ceramic compound comprising Y₄Al₂O₉ and a solid-solution of Y₂O₃—ZrO₂, in one embodiment the ceramic compound includes 62.93 molar ratio (mol %) Y₂O₃, 23.23 mol % ZrO₂ and 13.94 mol % Al₂O₃. In another embodiment, the ceramic compound can include Y₂O₃ in a range of 50-75 mol %, ZrO₂ in a range of 10-30 mol % and Al₂O₃ in a range of 10-30 mol %. In another embodiment, the ceramic compound can include Y₂O₃ in a range of 40-100 mol %, ZrO₂ in a range of 0.1-60 mol % and Al₂O₃ in a range of 0.1-10 mol %. In another embodiment, the ceramic compound can include Y₂O₃ in a range of 40-60 mol %, ZrO₂ in a range of 35-50 mol % and Al₂O₃ in a range of 10-20 mol %. In another embodiment, the ceramic compound can include Y₂O₃ in a range of 40-50 mol %, ZrO₂ in a range of 20-40 mol % and Al₂O₃ in a range of 20-40 mol %. In another embodiment, the ceramic compound can include Y₂O₃ in a range of 80-90 mol %, ZrO₂ in a range of 0.1-20 mol % and Al₂O₃ in a range of 10-20 mol %. In another embodiment, the ceramic compound can include Y₂O₃ in a range of 60-80 mol %, ZrO₂ in a range of 0.1-10 mol % and Al₂O₃ in a range of 20-40 mol %. In another embodiment, the ceramic compound can include Y₂O₃ in a range of 40-60 mol %, ZrO₂ in a range of 0.1-20 mol % and Al₂O₃ in a range of 30-40 mol %. In other embodiments, other distributions may also be used for the ceramic compound.

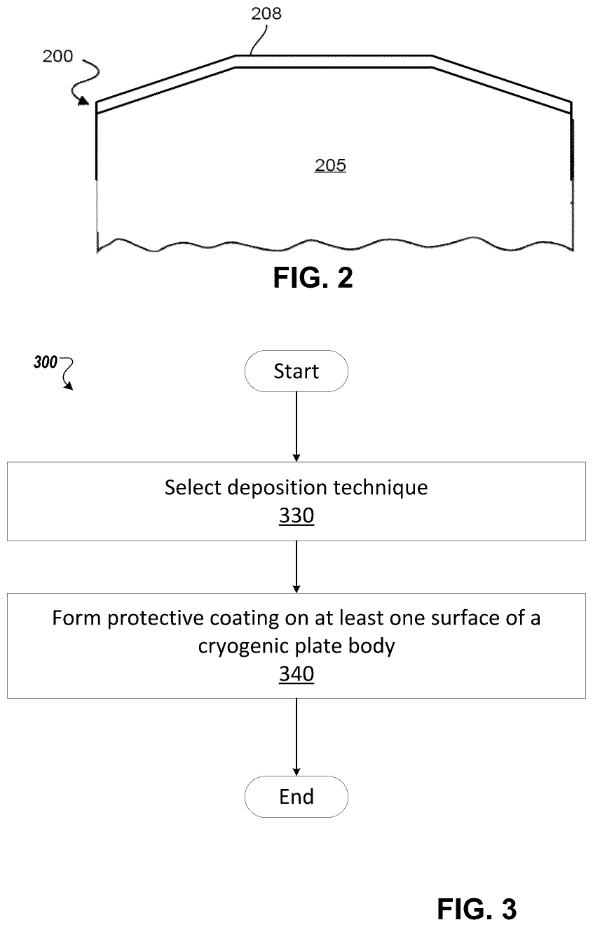

In some embodiments, the protective coating 163 includes Y₂O₃. In some embodiments, the protective coating 163 includes YF3. In some embodiments, the protective coating 163 includes YₓO_{y}F_{z}, where the ratio of oxygen to fluorine can be tailored. The protective ceramic material coating is described in more detail with reference to FIG. 2 and the process of coating an article with the protective ceramic material coating is described in more detail with reference to FIG. 3.

FIG. 1B is a simplified schematic diagram of a substrate processing system 100B that includes a cryogenic pump 160, according to some embodiments. In some embodiments, a cryogenic pump 160 is coupled and/or disposed at least partially within processing chamber 100A. A refrigeration unit 170 may supply cooled refrigerant to the cryogenic pump 160. In some embodiments, the refrigeration unit 170 includes a compressor 172 and a refrigerator 174. The compressor 172 and/or refrigerator 174 may together cool a refrigerant and provide the cooled refrigerant to a plate of the cryogenic pump 160. In some embodiments, the refrigerant is a gaseous refrigerant, such as helium. One or more tubes may convey the refrigerant to the cryogenic plate. The one or more tubes may include the protective coating 163 on an exterior surface. The refrigerant may be circulated through one or more interior passages and provided back to the refrigeration unit 170. In some embodiments, the cryogenic plate includes a protective coating as described herein. The protective coating may protect the cryogenic plate from corrosion caused by process chemistries within the processing chamber environment.

In some embodiments, a turbo pump 154 causes a vacuum to be drawn within the processing chamber 100A. A throttling gate valve 152 may regulate the flow of air (e.g., gas) from the processing chamber 100A past the cryogenic pump 160 to the turbo pump 154. The flow of air may be provided to a rough pump 156 via a foreline 184. The rough pump 156 may cause vacuum to be drawn within the processing chamber 100A in “rough” increments, while the turbo pump 154 may cause vacuum to be drawn within the processing chamber 100A in “fine” increments. In some embodiments, an isolation valve 182 is provided between the processing chamber 100A and the foreline 184. The isolation valve 182 may be closed to isolate the foreline 184 and/or the rough pump 156 from the processing chamber 100A.

FIG. 1C is a simplified schematic diagram of a cryogenic pump, according to some embodiments. In some embodiments, refrigeration unit 170 provides cooled refrigerant to cryogenic pump 160. The refrigerant may be cooled to a cryogenic temperature by the refrigeration 170. For example, and in some embodiments, the refrigeration unit 170 cools the refrigerant to a temperature less than approximately 200 Kelvin, such as approximately 150 Kelvin. The refrigerant may be a gaseous refrigerant such as helium. In some embodiments, the cooled refrigerant may be circulated within one or more interior passages of the cryogenic pump 160 and then returned to the refrigeration unit 170.

The cryogenic pump 160 may include one or more housings. In some embodiments, a first housing 166A houses a body 167A. Cooled refrigerant may flow through passages within the housing 166A to cool the body 167A. The housing 166A may isolate the body 167A and the refrigerant from the external environment. The body 167A may be in thermal communication with an arm 167B disposed within a second housing 166B. The arm 167B may be made of a thermally conductive material such as a metal. For example, the arm 167B may be made of aluminum or copper. “Thermal communication” may refer to a physical arrangement of two or more components that provides the ability for heat to be transferred between the two or more components, especially by conduction such as between the body 167A and the arm 167B. For example, two components that are in physical contact may be in thermal communication. In some embodiments, the arm 167B is in thermal communication with the cryogenic plate 162. In some embodiments, cooling of the body 167A (e.g., by the cooled refrigerant) causes the cryogenic plate 162 to be cooled by conduction via the arm 167B. In some embodiments, the cryogenic plate 162 is made up of a thermally conductive material, such as a metal. For example, and in some embodiments, the cryogenic plate 162 is made up of copper and/or a copper alloy, etc. In another example, the cryogenic plate 162 is made up of aluminum and/or an aluminum alloy.

In some embodiments, the cryogenic plate 162 (and the protective coating 163) is cooled to an operating temperature less than approximately 200 Kelvin, such as approximately 150 Kelvin. In some embodiments, the cryogenic plate 162 is cooled so that when water vapor 192 in the processing chamber comes into contact with the cryogenic plate 162, the water vapor 192 will condense and freeze on the cryogenic plate 162 (e.g., on the protective coating 163 on the cryogenic plate 162). Condensing and freezing of the water vapor 192 may reduce the partial pressure of H₂O within the processing chamber.

The cryogenic plate 162 may include a protective coating 163 on at least one surface. In some embodiments, the protective coating 163 is disposed on a top surface and/or a bottom surface of the cryogenic plate 162. The protective coating 163 may additionally be disposed on one or more circumferential surfaces of the cryogenic plate 162. As described herein, the protective coating 163 may be a protective ceramic material coating. In some embodiments, the protective coating 163 may include a rare earth oxide or SiO₂. In some embodiments, the protective coating 163 includes at least one of Y₃AL₅O₁₂ (YAG) or a solid solution of Y₂O₃ and ZrO₂. Any of the other aforementioned coatings may also be used. In some embodiments, the protective coating 163 includes Y₂O₃. In some embodiments, the protective coating 163 is substantially non-porous so that liquids condensed on the protective coating substantially cannot seep into and/or compromise the protective coating 163. For example, and in some embodiments, the protective coating 163 has a porosity less than 1%. In another example, and in some embodiments, the protective coating 163 has a porosity less than 0.1%. In some embodiments, the coefficient of thermal expansion of the protective coating 163 substantially matches the coefficient of thermal expansion of the cryogenic plate 162. This matching of coefficients of thermal expansion may be to reduce cracking in the protective coating caused by thermal expansion.

In some embodiments, the protective coating 163 does not materially alter the thermal conductance of the cryogenic plate 162. Therefore, the protective coating 163 may not degrade the cryogenic plate's ability to freeze and trap moisture, etc. For example, the protective coating 163 does not act as a thermal insulator between the cryogenic plate 162 and the environment within the processing chamber. Heat may be absorbed from the moisture in the environment and the moisture may condense and freeze on the cryogenic plate 162 uninhibited by the protective coating 163.

The cryogenic plate 162 may be configured to be disposed within a substrate process chamber. In some embodiments, the cryogenic plate 162 is disposed within a ring 168. The ring 168 may form part of the processing chamber. Components of the cryogenic pump 160 that are disposed within the ring 168 have additionally include the protective coating 163. For example, at least a portion of the arm 167B that extends into the ring 168 from the housing 166B may be coated with the protective coating 163. In some embodiments, the protective coating 163 has a thickness between approximately 50 nanometers and approximately 1,000 nanometers. In some embodiments, the protective coating 163 has a thickness between approximately 100 nanometers and approximately 700 nanometers. In some embodiments, the protective coating 163 has a thickness between approximately 200 nanometers and approximately 500 nanometers. In some embodiments, the protective coating 163 has a thickness between approximately 300 nanometers and approximately 400 nanometers.

FIG. 2 is a sectional view of a coated cryogenic pump component 200, in accordance with some embodiments. In an embodiment, the coated cryogenic pump component may comprise an article 205 and a protective ceramic material coating 208.

The protective ceramic material coating may comprise yttria (Y₂O₃), silica (SiO₂), Y₃Al₅O₁₂ (YAG), a solid solution of Y₂O₃ and ZrO₂, or a combination thereof, such as a solid solution of yttria and silica and/or a multiphase mixture, etc. Any of the other aforementioned coatings may also be used. In certain embodiments, the protective ceramic material coating may be predominantly yttria and a portion of the protective ceramic material coating may be substituted with silica so as to minimize the potential of yttrium metal contaminants getting deposited on substrates during processing. In some embodiments, an intermediate material coating may be included between the substrate and a silica top coating. The intermediate material coating may have a composition chosen to provide a gradient of thermal expansion coefficients from the substrate to the silica top coating.

In one embodiment, the protective ceramic material coating may comprise at least one phase material of yttria and silica. In certain embodiments, the protective ceramic material coating may consist of or consist essentially of at least one phase material of yttria and silica. In certain embodiments, the concentration of Y₂O₃ and of SiO₂ adds up to 100 molar %. In other embodiments, the at least one phase material may comprise additional constituents other than Y₂O₃ and SiO₂. In one embodiment, the protective ceramic material coating may consist of only Y₂O₃ and SiO₂ (in the form of one or more phases).

In one embodiment, the at least one phase material may comprise Y₂O₃ at a concentration of about 10 molar % to about 65 molar % and SiO₂ at a concentration of about 35 molar % to about 90 molar % to. In one embodiment, the at least one phase material may comprise Y₂O₃ at a concentration of about 20 molar % to about 60 molar % and SiO₂ at a concentration of about 40 molar % to about 80 molar %. In one embodiment, the at least one phase material may comprise Y₂O₃ at a concentration of about 25 molar % to about 55 molar % and SiO₂ at a concentration of about 45 molar % to about 75 molar %. In one embodiment, the at least one phase material may comprise Y₂O₃ at a concentration of about 40 molar % to about 50 molar % and SiO₂ at a concentration of about 50 molar % to about 60 molar %.

In one embodiment, the at least one phase material may comprise a composition selected from the group consisting of: a) Y₂O₃ at a concentration of about 65 molar % and SiO₂ at a concentration of about 35 molar %, b) Y₂O₃ at a concentration of about 60 molar % and SiO₂ at a concentration of about 40 molar %, c) Y₂O₃ at a concentration of about 55 molar % and SiO₂ at a concentration of about 45 molar %, d) Y₂O₃ at a concentration of about 50 molar % and SiO₂ at a concentration of about 50 molar %, e) Y₂O₃ at a concentration of about 45 molar % and SiO₂ at a concentration of about 55 molar %, f) Y₂O₃ at a concentration of about 40 molar % and SiO₂ at a concentration of about 60 molar %, g) Y₂O₃ at a concentration of about 35 molar % and SiO₂ at a concentration of about 65 molar %, h) Y₂O₃ at a concentration of about 30 molar % and SiO₂ at a concentration of about 70 molar %, i) Y₂O₃ at a concentration of about 25 molar % and SiO₂ at a concentration of about 75 molar %, j) Y₂O₃ at a concentration of about 20 molar % and SiO₂ at a concentration of about 80 molar %, k) Y₂O₃ at a concentration of about 15 molar % and SiO₂ at a concentration of about 85 molar %, and l) Y₂O₃ at a concentration of about 10 molar % and SiO₂ at a concentration of about 90 molar %.

In some embodiments, the protective ceramic material coating can include Y₂O₃ in a range of 70-90 mol % and ZrO₂ in a range of 10-30 mol %. In some embodiments, the protective ceramic material coating can include Y₂O₃ in a range of 40-70 mol % and ZrO₂ in a range of 30-60 mol %.

Any of the aforementioned protective coatings may include trace amounts of other materials such as ZrO₂, Al₂O₃, SiO₂, B₂O₃, Er₂O₃, Nd₂O₃, Nb₂O₅, CeO₂, Sm₂O₃, Yb₂O₃, or other oxides.

In one embodiment, EB-IAD is utilized to form the protective ceramic material coat 208. In one embodiment, IBS-IAD is utilized to form the protective ceramic material coat 208. In one embodiment, CVD is utilized to form the protective ceramic material coat 208. In one embodiment, PVD is utilized to form the protective ceramic material coat 208. In one embodiment, plasma spray is utilized to form the protective ceramic material coat 208. In one embodiment, ALD is utilized to form the protective ceramic material coat 208.

FIG. 3 is a flow chart showing a method 300 for coating an article, such as a cryogenic pump component, in accordance with one embodiment. At block 330, a deposition technique is selected for coating the article with the protective ceramic material coating. The deposition technique may be selected from ion assisted deposition (IAD), chemical vapor deposition (CVD), physical vapor deposition (PVD), atomic layer deposition (ALD), or plasma spray. Ceramic powders, gas precursors, etc. that are to be used to form the protective coating may be selected.

In one embodiment, the protective coating may comprise Y₂O₃, SiO₂, or a combination thereof. In one embodiment, the protective coating may consist of or consist essentially of yttria and silica. In certain embodiments, the concentration of Y₂O₃ and of SiO₂ adds up to 100 molar %. In other embodiments, the protective coating may comprise additional constituents other than Y₂O₃ and SiO₂. In other embodiments, the protective coating comprises Y₃Al₅O₁₂ (YAG).

In one embodiment, the protective coating includes Y₂O₃ at a concentration of about 10 molar % to about 65 molar % and SiO₂ at a concentration of about 35 molar % to about 90 molar % to. In one embodiment, the protective coating includes Y₂O₃ at a concentration of about 20 molar % to about 60 molar % and SiO₂ at a concentration of about 40 molar % to about 80 molar %. In one embodiment, the protective coating includes Y₂O₃ at a concentration of about 25 molar % to about 55 molar % and SiO₂ at a concentration of about 45 molar % to about 75 molar %. In one embodiment, the protective coatings includes Y₂O₃ at a concentration of about 40 molar % to about 50 molar % and SiO₂ at a concentration of about 50 molar % to about 60 molar %.

In one embodiment, the protective coating includes a composition selected from the group consisting of: a) Y₂O₃ at a concentration of about 65 molar % and SiO₂ at a concentration of about 35 molar %, b) Y₂O₃ at a concentration of about 60 molar % and SiO₂ at a concentration of about 40 molar %, c) Y₂O₃ at a concentration of about 55 molar % and SiO₂ at a concentration of about 45 molar %, d) Y₂O₃ at a concentration of about 50 molar % and SiO₂ at a concentration of about 50 molar %, e) Y₂O₃ at a concentration of about 45 molar % and SiO₂ at a concentration of about 55 molar %, f) Y₂O₃ at a concentration of about 40 molar % and SiO₂ at a concentration of about 60 molar %, g) Y₂O₃ at a concentration of about 35 molar % and SiO₂ at a concentration of about 65 molar %, h) Y₂O₃ at a concentration of about 30 molar % and SiO₂ at a concentration of about 70 molar %, i) Y₂O₃ at a concentration of about 25 molar % and SiO₂ at a concentration of about 75 molar %, j) Y₂O₃ at a concentration of about 20 molar % and SiO₂ at a concentration of about 80 molar %, k) Y₂O₃ at a concentration of about 15 molar % and SiO₂ at a concentration of about 85 molar %, and l) Y₂O₃ at a concentration of about 10 molar % and SiO₂ at a concentration of about 90 molar %.

At block 340, a protective coating may be formed on at least one surface of a cryogenic plate body (e.g., cryogenic plate 162 described herein above). In some embodiments, the protective coating includes a rare earth oxide or SiO₂. In some embodiments, the protective coating includes a mixture of yttria and silica. Any of the other aforementioned coatings (e.g., YAG, Y₂O₃—ZrO₂ solid solution, etc.) may also be used. The ceramic protective coating described herein above may be deposited on the cryogenic plate using the deposition technique selected at block 330.

In some embodiments, the method of coating an article (e.g., a cryogenic pump component) may include cooling the article to an intermediate temperature. The intermediate temperature may be warmer than an operating temperature of the article. For example, a cryogenic plate may have an operating temperature less than approximately 200 Kelvin, such as approximately 150 Kelvin. The uncoated cryogenic plate may be cooled to an intermediate temperature that is warmer than the operating temperature. For example, and in some embodiments, the intermediate temperature may be between 150 Kelvin and 300 Kelvin, between 200 Kelvin and 300 Kelvin, between 230 Kelvin and 270 Kelvin, or between 240 Kelvin and 260 Kelvin. While cooled to the intermediate temperature, the uncoated cryogenic plate may be coated with the protective coating. The coating may be performed while the article is cooled to the intermediate temperature in embodiments. In embodiments, forming the coating on a cooled surface reduces the amount of compressive stress that the coating will experience when used at operating temperatures.

In some embodiments, the method of coating an article (e.g., a cryogenic pump component) with a protective ceramic material coating may further include forming one or more features in the protective ceramic material coating. Forming one or more features may include grinding and/or polishing the protective ceramic material coating, drilling holes in the protective ceramic material coating, cutting and/or shaping the protective ceramic material coating, roughening the protective ceramic material coating (e.g., by bead blasting), forming mesas on the protective ceramic material coating, and so forth. In one embodiment, the one or more features may comprise at least one of holes, channels, or mesas.

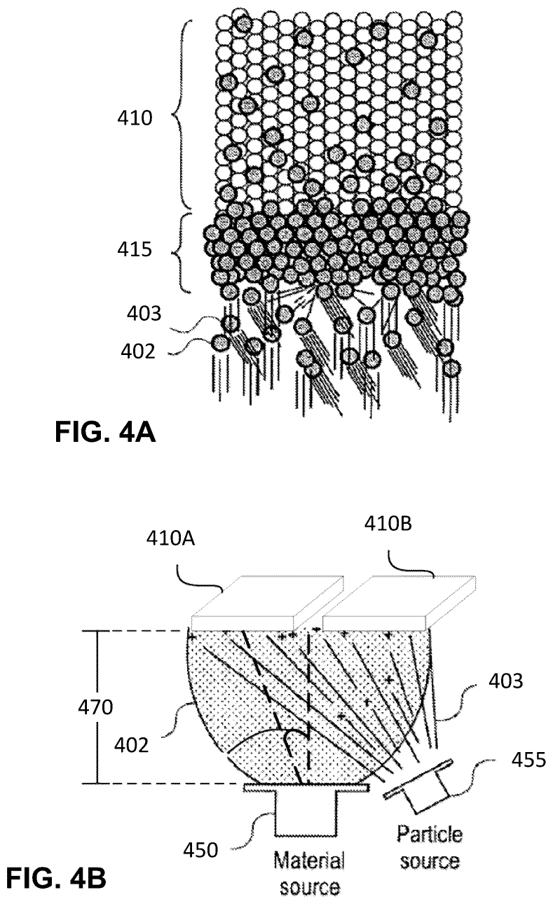

FIG. 4A depicts a deposition mechanism applicable to a variety of deposition techniques utilizing energetic particles such as IAD. Exemplary IAD methods include deposition processes which incorporate ion bombardment, such as evaporation (e.g., activated reactive evaporation (ARE) or electron beam ion assisted deposition (EB-IAD)) and sputtering (e.g., ion beam sputtering ion assisted deposition (IBS-IAD)) in the presence of ion bombardment to form protective coatings as described herein. EB-IAD may be performed by evaporation. IBS-IAD may be performed by sputtering a solid material source. Any of the IAD may be performed in the presence of a reactive gas species (e.g., O₂, N₂, CO, halogens, etc) and/or in the presence of non-reactive species (e.g., Ar).

As shown, the protective coat 415 is formed on an article 410 or on multiple articles 410A, 410B (shown in FIG. 4B) by an accumulation of deposition materials 402 in the presence of energetic particles 403 such as ions (e.g., oxygen ions or nitrogen ions). The deposition materials 402 may include atoms, ions, radicals, or their mixture. The energetic particles 403 may impinge and compact the protective coat 415 as it is formed.

FIG. 4B depicts a schematic of an IAD apparatus. As shown, a material source 450 provides a flux of deposition materials 402 while an energetic particle source 455 provides a flux of the energetic particles 403, both of which impinge upon the article 410 (shown in FIG. 4A), 410A, 410B throughout the IAD process. The energetic particle source 455 may be an oxygen, nitrogen or other ion source. The energetic particle source 455 may also provide other types of energetic particles such as inert radicals, neutron atoms, and nano-sized particles which come from particle generation sources (e.g., from plasma, reactive gases or from the material source that provide the deposition materials). IAD may utilize one or more plasmas (for example, argon plasma or argon-oxygen plasma) or beams to provide the material and energetic particles sources. Reactive species may also be provided during deposition of the plasma resistant coating.

With IAD processes, energetic particles 403 may be controlled by the energetic particle source 455 (e.g., energetic ion source) independently of other deposition parameters. The energy (e.g., velocity), density, working distance and incident angle of the energetic particle flux may be adjusted to control a composition, structure, crystalline orientation and grain size of the protective coat. Additional parameters that may also be adjusted are the article's temperature during deposition as well as the duration of the deposition. In certain embodiments, the working distance 470 between the material source 450 and the article 410A, 410B range from about 0.2 to about 2.0 meters or from about 0.2 to about 1.0 meters. In certain embodiments, the protective coating may have a non-uniformity of up to about 5-10%. In certain embodiments, the incident angle (i.e. the angle at which the deposition material from the material source strike the article) ranges from about 10-90 degrees or may be about 30 degrees.

IAD coatings can be applied over a wide range of surface conditions with roughness from about 0.5 micro-inches (pin) to about 180 pin. However, smoother surface facilitates uniform coating coverage. The coating thickness can be up to about 1000 micrometers (μm). IAD coatings can be amorphous or crystalline depending on the material used to create the coating. Amorphous coatings are more conformal and reduce lattice mismatch induced epitaxial cracks whereas crystalline coatings are more erosion resistant.

Coating architecture can be a bi-layer or a multi-layer structure. In a bilayer architecture, an amorphous layer can be deposited as a buffer layer to minimize epitaxial cracks followed by a crystalline layer on the top which might be erosion resistant. In a multi-layer design, layer materials may be used to cause a smooth thermal gradient from the substrate to the top layer. Although possible variations in coating architecture are described herein with respect to IAD, it should be understood that such variations may also be accomplished if and/or when the protective coating is deposited by other techniques discussed herein (such as CVD, PVD other than IAD, ALD, and plasma spray) as well as by other techniques understood as equivalent to the techniques enumerated herein by one of ordinary skill in the art.

Co-deposition of multiple materials using multiple electron beam (e-beam) guns can be achieved to create thicker coatings as well as layered architectures. For example, two material sources having the same material type may be used at the same time. This may increase a deposition rate and a thickness of the protective coat. In another example, two material sources may be different ceramic materials or different metallic materials. A first electron beam gun may bombard a first material source to deposit a first protective coat, and a second electron beam gun may subsequently bombard the second material source to form a second protective coat having a different material composition than the first protective coat. Alternatively, the two electron beam guns may bombard the two material sources simultaneously to create a complex ceramic compound. Accordingly, two different metallic targets may be used rather than a single metal alloy to form a complex ceramic compound. Although co-deposition is described herein with respect to IAD, it should be understood that such co-deposition may also be accomplished if and/or when the protective coating is deposited by other techniques discussed herein (such as CVD, PVD other than IAD, ALD, and plasma spray) as well as by other techniques understood as equivalent to the techniques enumerated herein by one of ordinary skill in the art.

Post coating heat treatment can be used to achieve improved coating properties. For example, it can be used to convert an amorphous coating to a crystalline coating with higher erosion resistance. Although post coating heat treatment is described herein with respect to IAD, it should be understood that such post coating heat treatment may also be accomplished if and/or when the protective coating is deposited by other techniques discussed herein (such as CVD, PVD other than IAD, ALD, and plasma spray) as well as by other techniques understood as equivalent to the techniques enumerated herein by one of ordinary skill in the art.

The IAD apparatus depicted in FIG. 4B may be used to deposit, in accordance with the IAD mechanism depicted in FIG. 4A, a protective coat that is resistant to erosion and/or corrosion in embodiments. Protective coat 415 may comprise a ceramic material such as Y₂O₃, SiO₂, or any combination thereof including but not limited to a Y₂O₃ and SiO₂ solid solution or multiphase mixture.

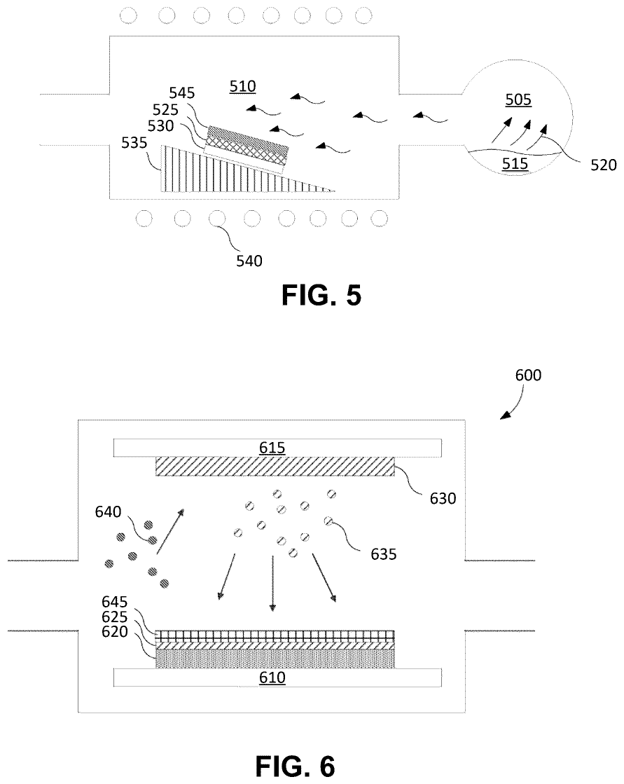

In some embodiments, the protective coating may be deposited on a surface of an article via CVD. An exemplary CVD system is illustrated in FIG. 5. The system comprises a chemical vapor precursor supply system 505 and a CVD reactor 510. The role of the vapor precursor supply system 505 is to generate vapor precursors 520 from a starting material 515, which could be in a solid, liquid, or gas form. The vapors may subsequently be transported into CVD reactor 510 and get deposited as a protective coat 525 and/or 545 on the surface of article 530, in accordance with an embodiment, which may be positioned on article holder 535.

CVD reactor 510 heats article 530 to a deposition temperature using heater 540. In some embodiments, the heater may heat the CVD reactor's wall (also known as “hot-wall reactor”) and the reactor's wall may transfer heat to the article. In other embodiments, the article alone may be heated while maintaining the CVD reactor's wall cold (also known as “cold-wall reactor”). It is to be understood that the CVD system configuration should not be construed as limiting. A variety of equipment could be utilized for a CVD system and the equipment is chosen to obtain optimum processing conditions that may give a coating with uniform thickness, surface morphology, structure, and composition.

The various CVD techniques include the following phases: (1) generate active gaseous reactant species (also known as “precursors”) from the starting material; (2) transport the precursors into the reaction chamber (also referred to as “reactor”); (3) absorb the precursors onto the heated article; (4) participate in a chemical reaction between the precursor and the article at the gas-solid interface to form a deposit and a gaseous by-product; and (5) remove the gaseous by-product and unreacted gaseous precursors from the reaction chamber.

Suitable CVD precursors may be stable at room temperature, may have low vaporization temperature, can generate vapor that is stable at low temperature, have suitable deposition rate (low deposition rate for thin film coatings and high deposition rate for thick film coatings), relatively low toxicity, be cost effective, and relatively pure. For some CVD reactions, such as thermal decomposition reaction (also known as “pyrolysis”) or a disproportionation reaction, a chemical precursor alone may suffice to complete the deposition. For other CVD reactions, other agents (listed in Table 1 below) in addition to a chemical precursor may be utilized to complete the deposition.

TABLE 1
Chemical Precursors and Additional Agents
Utilized in Various CVD Reactions

| CVD reaction | Chemical Precursor | Additional Agents |
|---|---|---|
| Thermal Decomposition | Halides | N/A |
| (Pyrolysis) | Hydrides | |
| | Metal carbonyl | |
| | Metalorganic | |
| Reduction | Halides | Reducing agent |
| Oxidation | Halides | Oxidizing agent |
| | Hydrides | |
| | Metalorganic | |
| Hydrolysis | Halides | Hydrolyzing agent |
| Nitridation | Halides | Nitriding agent |
| | Hydrides | |
| | Halohydrides | |
| Disproportionation | Halides | N/A |

CVD has many advantages including its capability to deposit highly dense and pure coatings and its ability to produce uniform films with good reproducibility and adhesion at reasonably high deposition rates. Layers deposited using CVD in embodiments may have a porosity of below 1%, and a porosity of below 0.1% (e.g., around 0%). Therefore, it can be used to uniformly coat complex shaped components and deposit conformal films with good conformal coverage (e.g., with substantially uniform thickness). CVD may also be utilized to deposit a film made of a plurality of components, for example, by feeding a plurality of chemical precursors at a predetermined ratio into a mixing chamber and then supplying the mixture to the CVD reactor system.

The CVD reactor 510 may be used to form a protective coat that is resistant to erosion and/or corrosion in embodiments. Protective coat 525 and/or 545 may comprise a ceramic material such as Y₂O₃, SiO₂, Y₃Al₅O₁₂ (YAG), a solid solution of Y₂O₃ and ZrO₂, any of the other aforementioned coatings, or any combination thereof. The protective coat may comprise a bilayer or a multilayer architecture, various layers may have similar or different thicknesses, and the layers may independently be crystalline or amorphous. The materials forming the protective coat may be co-deposited. In some embodiments, the protective coat may be subject to post coating heat treatment. In some embodiments, the protective coat may be subject to post coating processing to form one or more features therein.

In some embodiments, the protective coating may be deposited on a surface of an article via a PVD technique (other than the IAD technique discussed earlier). PVD processes may be used to deposit thin films with thicknesses ranging from a few nanometers to several micrometers. The various PVD processes share three fundamental features in common: (1) evaporating the material from a solid source with the assistance of high temperature or gaseous plasma; (2) transporting the vaporized material in vacuum to the article's surface; and (3) condensing the vaporized material onto the article to generate a thin film layer. An illustrative PVD reactor is depicted in FIG. 6 and discussed in more detail below.

FIG. 6 depicts a deposition mechanism applicable to a variety of PVD techniques and reactors. PVD reactor chamber 600 may comprise a plate 610 adjacent to the article 620 and a plate 615 adjacent to the target 630. Air may be removed from reactor chamber 600, creating a vacuum. Then argon gas may be introduced into the reactor chamber, voltage may be applied to the plates, and a plasma comprising electrons and positive argon ions 640 may be generated. Positive argon ions 640 may be attracted to negative plate 615 where they may hit target 630 and release atoms 635 from the target. Released atoms 635 may get transported and deposited as a thin film protective coat 625 and/or 645 onto article 620, in accordance with an embodiment.

The PVD reactor chamber 600 may be used to form a protective ceramic material coat in embodiments. Protective coat 625 and/or 645 may comprise a ceramic material such as Y₂O₃, SiO₂, Y₃Al₅O₁₂ (YAG), a solid solution of Y₂O₃ and ZrO₂, any of the other aforementioned coatings, or any combination thereof. The protective coat may comprise a bilayer or a multilayer architecture, various layers may have similar or different thicknesses, and the layers may independently be crystalline or amorphous. The materials forming the protective coat may be co-deposited. In some embodiments, the protective coat may be subject to post coating heat treatment. In some embodiments, the protective coat may be subject to post coating processing to form one or more features therein.

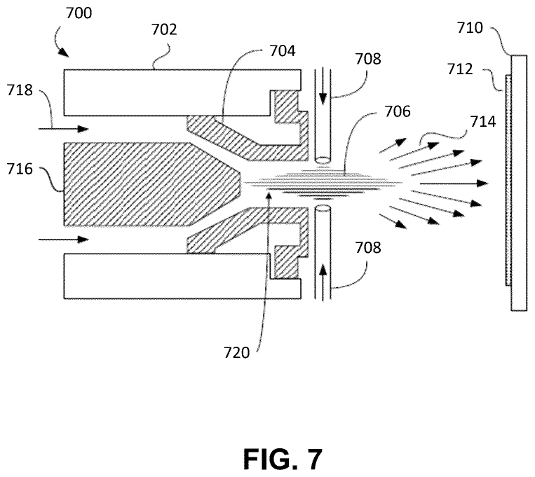

FIG. 7 illustrates a cross-sectional view of a system 700 for plasma spraying a coating on an article. The system 700 is a type of thermal spray system. In a plasma spray system 700, an arc 706 is formed between two electrodes, an anode 704 and a cathode 716, through which a plasma gas 718 is flowing via a gas delivery tube 702. The plasma gas 718 may be a mixture of two or more gases. Examples of gas mixtures suitable for use in the plasma spray system 700 include, but are not limited to, argon/hydrogen, argon/helium, nitrogen/hydrogen, nitrogen/helium, or argon/oxygen. The first gas (gas before the forward-slash) represents a primary gas and the second gas (gas after the forward-slash) represents a secondary gas. A gas flow rate of the primary gas may differ from a gas flow rate of the secondary gas. In one embodiment, a gas flow rate for the primary gas is about 30 L/min and about 400 L/min. In one embodiment, a gas flow rate for the secondary gas is between about 3 L/min and about 100 L/min.

As the plasma gas is ionized and heated by the arc 706, the gas expands and is accelerated through a shaped nozzle 720, creating a high velocity plasma stream.

Powder 708 is injected into the plasma spray or torch (e.g., by a powder propellant gas) where the intense temperature melts the powder and propels the material as a stream of molten particles 714 towards the article 710. Upon impacting the article 710, the molten powder flattens, rapidly solidifies, and forms a coating 712, which adheres to the article 710. Coating 712 may be a protective ceramic material coating according to an embodiment. The parameters that affect the thickness, density, and roughness of the coating 712 include type of powder, powder size distribution, powder feed rate, plasma gas composition, plasma gas flow rate, energy input, torch offset distance, substrate cooling, etc.

Plasma spray apparatus 700 may be used to form a protective ceramic material coat in embodiments. Protective coat 712 may comprise a ceramic material such as Y₂O₃, SiO₂, Y₃AL₅O₁₂ (YAG), a solid solution of Y₂O₃ and ZrO₂, or any combination thereof. The protective coat may comprise a bilayer or a multilayer architecture, various layers may have similar or different thicknesses, and the layers may independently be crystalline or amorphous. The materials forming the protective coat may be co-deposited. In some embodiments, the protective coat may be subject to post coating heat treatment. In some embodiments, the protective coat may be subject to post coating processing to form one or more features therein.

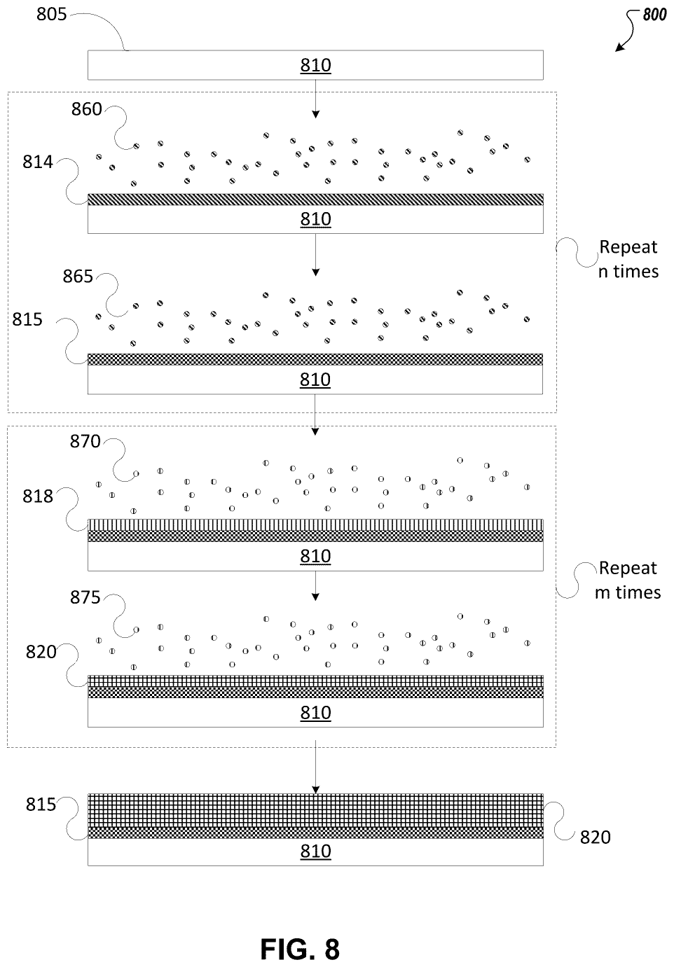

FIG. 8 depicts a deposition process 800 in accordance with a variety of ALD techniques. Various types of ALD processes exist and the specific type may be selected based on several factors such as the surface to be coated, the coating material, chemical interaction between the surface and the coating material, etc. The general principle of an ALD process comprises growing or depositing a thin film layer by repeatedly exposing the surface to be coated to sequential alternating pulses of gaseous chemical precursors that chemically react with the surface one at a time in a self-limiting manner.

FIG. 8 illustrates an article 810 having a surface 805. Each individual chemical reaction between a precursor and the surface is known as a “half-reaction.” During each half reaction, a precursor is pulsed onto the surface for a period of time sufficient to allow the precursor to fully react with the surface. The reaction is self-limiting as the precursor will react with a finite number of available reactive sites on the surface, forming a uniform continuous adsorption layer on the surface. Any sites that have already reacted with a precursor will become unavailable for further reaction with the same precursor unless and/or until the reacted sites are subjected to a treatment that will form new reactive sites on the uniform continuous coating. Exemplary treatments may be plasma treatment, treatment by exposing the uniform continuous adsorption layer to radicals, or introduction of a different precursor able to react with the most recent uniform continuous film layer adsorbed to the surface.

In FIG. 8, article 810 having surface 805 may be introduced to a first precursor 860 for a first duration until a first half reaction of the first precursor 860 with surface 805 partially forms film layer 815 by forming an adsorption layer 814. Subsequently, article 810 may be introduced to a first reactant 865 that reacts with the adsorption layer 814 to fully form the layer 815. The first precursor 860 may be a precursor for yttrium, a precursor for silicon, or another metal, for example. The first reactant 865 may be an oxygen reactant if the layer 815 is an oxide (e.g. yttria, silica, YAG, or a solid solution of Y₂O₃ and ZrO₂, or a combination thereof, etc.). The article 810 may also be exposed to the first precursor 860 and first reactant 865 up to n number of times to achieve a target thickness for the layer 815. n may be an integer from 1 to 100, for example.

Film layer 815 may be a uniform, continuous and conformal. The film layer 815 may also have a very low porosity of less than 1% in embodiments, less than 0.1% in some embodiments, or approximately 0% in further embodiments. Subsequently, article 810 having surface 805 and film layer 815 may be introduced to a second precursor 870 that reacts with layer 815 to partially form a second film layer 820 by forming a second adsorption layer 818. Subsequently, article 810 may be introduced to another reactant 875 that reacts with adsorption layer 818 leading to a second half reaction to fully form the layer 820. The article 810 may alternately be exposed to the second precursor 870 and second reactant 875 up to m number of times to achieve a target thickness for the layer 820. m may be an integer from 1 to 100, for example. The second film layer 820 may be uniform, continuous and conformal. The second film layer 820 may also have a very low porosity of less than 1% in some embodiments, less than 0.1% in some embodiments, or approximately 0% in further embodiments.

In a similar manner, article 810 may continue to be introduced sequentially to the same or to other precursors and reactants until a final protective ceramic material coating according to an embodiment is formed.

In one embodiment, the final protective ceramic material coating may comprise a bilayer or a multilayer architecture. In one embodiment, the final protective ceramic material coating may have alternating layers. In one embodiment, the alternating layers may have the same or different thickness. The layers may independently be crystalline or amorphous.

In certain embodiments, the ALD deposition may comprise exposing article, e.g., article 810, to multiple precursors, e.g. a yttrium-containing precursor, a silicon-containing precursor, a zirconium-containing precursor, and/or an aluminum-containing precursor, and co-depositing the different precursors simultaneously. The ratio of the precursors may be selected to achieve a desired coating composition. Subsequently, article 810 may be exposed to a reactant such as an oxygen-containing reactant to form a final protective ceramic material coating comprising a plurality of oxides (e.g., yttria and silica).

In certain embodiments, the bilayer, multilayer, and/or co-deposited layer forming the final protective ceramic material coating may be annealed and/or interdiffused, for instance, through post-coating heat treatment. In some embodiments, a post deposition annealing process is not performed and instead already deposited layers interdiffuse during deposition of subsequent layers. In some embodiments, the protective coat may be subject to post coating processing to form one or more features therein.

The surface reactions (e.g., half-reactions) described above, such as the reaction between the article's surface and the precursor(s) or the reaction between the precursor(s) and the reactant(s), are done sequentially. Prior to introduction of a new precursor(s) and/or a new reactant(s), the chamber in which the ALD process takes place may be purged with an inert carrier gas (such as nitrogen or air) to remove any unreacted precursors and/or reactants and/or surface-precursor reaction byproducts.

ALD processes may be conducted at various temperatures. The optimal temperature range for a particular ALD process is referred to as the “ALD temperature window.” Temperatures below the ALD temperature window may result in poor growth rates and non-ALD type deposition. Temperatures above the ALD temperature window may result in thermal decomposition of the article or rapid desorption of the precursor. The ALD temperature window may range from about 200° C. to about 400° C. In some embodiments, the ALD temperature window is between about 150° C. to about 350° C.

The ALD process allows for conformal film layers having uniform film thickness on articles and surfaces having complex geometric shapes, holes with large aspect ratios, and three-dimensional structures. Sufficient exposure time of the precursors to the surface enables the precursors to disperse and fully react with the surface in its entirety, including all of its three-dimensional complex features. The exposure time utilized to obtain conformal ALD in high aspect ratio structures is proportionate to the square of the aspect ratio and can be predicted using modeling techniques.

The final protective ceramic material coatings deposited by the ALD process discussed above may comprise a ceramic material such as Y₂O₃, SiO₂, or any combination thereof including but not limited to a Y₂O₃ and SiO₂ solid solution or a multiphase mixture, YAG, or a solid solution of Y₂O₃ and ZrO₂.

Article 410 in FIG. 4A, articles 410A and 410B in FIG. 4B, article 530 in FIG. 5, article 620 in FIG. 6, article 710 in FIG. 7, article 810 in FIG. 8, and all other articles discussed herein may represent various cryogenic pump components including but not limited to a cryogenic plate and so on. The articles and their surfaces may be made from a metal (such as aluminum, stainless steel, copper, etc.), a ceramic, a metal-ceramic composite, a polymer, a polymer ceramic composite, or other suitable materials, and may further comprise materials such as AlN, Si, SiC, Al₂O₃, SiO₂, and so on.

With the IAD, CVD, PVD, ALD, and plasma spray techniques, protective ceramic material coatings comprising Y₂O₃, SiO₂, Y₃Al₅O₁₂ (YAG), a solid solution of Y₂O₃ and ZrO₂, or any combination thereof, can be formed. The protective ceramic material coatings disclosed herein provide good erosion and/or corrosion resistance to the coated article. The beneficial properties of the protective ceramic material coatings disclosed herein may be independent from the deposition techniques in certain embodiments. In certain embodiments, the beneficial properties observed in a protective coating deposited by CVD, PVD other than IAD, ALD, and/or plasma spray may be comparable or superior to those observed in a protective coating that is deposited by IAD.

Exemplary yttrium-containing precursors that may be utilized with the CVD and ALD coating deposition techniques include, but are not limited to, tris(N,N-bis(trimethylsilyl)amide) yttrium (III), yttrium (III) butoxide, tris(cyclopentadienyl) yttrium (III), and Y(thd)3 (thd=2,2,6,6-tetramethyl-3,5-heptanedionato).

Exemplary silicon-containing precursors that may be utilized with the ALD and CVD coating deposition techniques include, but are not limited to, 2, 4, 6, 8-tetramethylcyclotetrasiloxane, dimethoxydimethylsilane, disilane, methylsilane, octamethylcyclotetrasiloxane, silane, tris(isopropoxy) silanol, tris(tert-butoxy) silanol, and tris(tert-pentoxy) silanol.

Exemplary aluminum-containing precursors may include, without limitations, triethylaluminum (TMA), diethylaluminum ethoxide, tris(ethylmethylamido) aluminum, aluminum sec-butoxide, aluminum tribromide, aluminum trichloride, triethylaluminum, triisobutylaluminum, trimethylaluminum, or tris(diethylamido) aluminum. In one embodiment, the aluminum precursor used may be TMA.

Exemplary zirconium-containing precursors may include, without limitations, zirconium (IV) bromide, zirconium (IV) chloride, zirconium (IV) tert-butoxide, tetrakis(diethylamido) zirconium (IV), tetrakis(dimethylamido) zirconium (IV), or tetrakis(ethylmethylamido) zirconium (IV).

Exemplary oxygen-containing reactants that may be utilized with the various coating deposition techniques identified herein and their equivalent include, but are not limited to, ozone, water vapor, and oxygen radicals.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular embodiments may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.”

Reference throughout this specification to numerical ranges should not be construed as limiting and should be understood as encompassing the outer limits of the range as well as each number and/or narrower range within the enumerated numerical range.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A cryogenic pump, comprising:
a refrigeration unit; and
a cryogenic plate coupled with the refrigeration unit, wherein the cryogenic plate comprises:
a plate body; and
a protective coating on at least one surface of the plate body, wherein the protective coating comprises at least one of a rare earth oxide or SiO₂.

2. The cryogenic pump of claim 1, wherein the protective coating comprises Y₂O₃.

3. The cryogenic pump of claim 1, wherein the protective coating comprises at least one of Y₃AL₅O₁₂ (YAG) or a solid solution of Y₂O₃ and ZrO₂.

4. The cryogenic pump of claim 1, wherein the cryogenic plate is configured to be disposed within a substrate process chamber.

5. The cryogenic pump of claim 4, wherein the substrate process chamber comprises an epitaxial reactor.

6. The cryogenic pump of claim 1, wherein the refrigeration unit is configured to cool the cryogenic plate to an operating temperature less than approximately 200 Kelvin.

7. The cryogenic pump of claim 1, wherein the plate body forms one or more interior passages, and wherein the refrigeration unit is configured to circulate a refrigerant through the one or more interior passages, the cryogenic pump further comprising:
one or more tubes configured to convey the refrigerant between the refrigeration unit and the cryogenic plate, wherein the one or more tubes comprise the protective coating on at least an exterior surface of the one or more tubes.

8. The cryogenic pump of claim 1, wherein the plate body comprises at least one of copper or aluminum.

9. The cryogenic pump of claim 1, wherein the protective coating has a thickness between approximately 50 nanometers and approximately 1,000 nanometers.

10. The cryogenic pump of claim 9, wherein the thickness is between approximately 200 nanometers and approximately 500 nanometers.

11. A method, comprising:
forming a protective coating on at least one surface of a cryogenic plate body, wherein the protective coating comprises at least one of a rare earth oxide or SiO₂.

12. The method of claim 11, wherein the protective coating is formed using a process selected from ion assisted deposition (IAD), chemical vapor deposition (CVD), physical vapor deposition (PVD), atomic layer deposition (ALD), or plasma spraying.

13. The method of claim 11, wherein the protective coating comprises Y₂O₃.

14. The method of claim 11, further comprising:
cooling the cryogenic plate body to an intermediate temperature warmer than an operating temperature for the cryogenic plate body, wherein the protective coating is formed on the at least one surface at the intermediate temperature.

15. The method of claim 14, wherein the intermediate temperature is warmer than approximately 200 Kelvin.

16. The method of claim 11, wherein the protective coating has a thickness between approximately 50 nanometers and 1,000 nanometers.

17. A process chamber, comprising:
chamber body; and
a cryogenic plate disposed within the chamber body, wherein the cryogenic plate comprises:
a plate body; and
a protective coating on at least one surface of the plate body, wherein the protective coating comprises at least one of a rare earth oxide or SiO₂.

18. The process chamber of claim 17, wherein the protective coating comprises Y₂O₃.

19. The process chamber of claim 17, wherein the plate body comprises copper.

20. The process chamber of claim 17, wherein the protective coating has a thickness between approximately 50 nanometers and 1,000 nanometers.
